(19) United States
(12) Patent Application Publication
(10) Pub. No.: US 2008/0111219 A1
(43) Pub. Date: May 15, 2008

(54) PACKAGE DESIGNS FOR VERTICAL CONDUCTION DIE

(75) Inventors: James Harnden, Hollister, CA (US); Anthony Chia, Singapore (SG); Liming Wong, Shanghai (CN); Hongbo Yang, Shanghai (CN)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: GEM Services, Inc., Santa Clara, CA (US)

(21) Appl. No.: 11/559,819

(22) Filed: Nov. 14, 2006

(51) Int. Cl. H01L 23/495; H01L 21/00

(52) U.S. Cl. 257/676; 438/106; 257/E23.031; 257/E21.001

(57) ABSTRACT

Embodiments in accordance with the present invention relate to packaging designs for vertical conduction semiconductor devices which include low electrical resistance contacts with a top surface of the die. In one embodiment, the low resistance contact may be established by the use of Aluminum ribbon bonding with one side of a leadframe, or with both of opposite sides of a leadframe. In accordance with a particular embodiment, the vertical conduction device may be housed within a Quad Flat No-lead (QFN) package modified for that purpose.

### BACKGROUND OF THE INVENTION

Widespread demand for “power management semiconductor products”, discrete, integrated, and combinations of technologies in very high volume portable consumer products (such as portable telecom, digital cameras, MP3 players, pocket computers, etc.), has spawned new products to generate and switch a host of voltages from batteries. The pressure of large volume production has in turn driven the rapid evolution of specialized semiconductor products, and given rise to successive generations of device packages exhibiting reduced vertical profiles, smaller footprints, lower thermal and electrical resistance, and cheaper manufacturing cost.

Some acceptable alternatives exist for packages requiring only a single low resistance contact to one side of the housed die. An example of such a die having contact on only a single side includes an integrated circuits, a power integrated circuit (power ICs), and a lateral discrete.

However, the low resistance per unit area exhibited by vertical conduction discretes devices (such as conventional Mosfets) necessitates establishing a very low resistance contact to both top and bottom surfaces of the die. This requirement has led to development of unique combinations of packages, processes and materials.

One goal affecting the design of previous generations of packages for vertical conduction discrete devices, was reduction of the electrical resistance exhibited by the package. In this previous generation of packages, conventional 2 mil thick gold bondwires were replaced with alternatives exhibiting lower electrical resistance. Another goal affecting design of previous generations of packages was the elimination of leads thereby, allowing both lower thermal resistance and thinner package profile.

One key to designing the next generation of packages for vertical conduction discrete devices will be to focus those same goals into manufacturable and cost effective standard packages. Another key for future package designs will be to offer ways to economically interconnect different technology die, and even passive components, with the power management die. Such interconnection is advantageously accomplished with lower impedance, lower inductance, and higher frequencies than can be achieved by interconnecting such devices in separate packages.

Therefore, there is a need in the art for improved techniques for fabricating packages for vertical conduction discrete devices, and other die requiring low resistance contacts on both sides.

### BRIEF SUMMARY OF THE INVENTION

Embodiments in accordance with the present invention relate to packaging designs for vertical conduction semiconductor devices which include low electrical resistance contacts with a top surface of the die. In one embodiment, the low resistance contact may be established by the use of Aluminum ribbon bonding with one side of a leadframe, or with both of opposite sides of the leadframe. In accordance with a particular embodiment, the vertical conduction device may be housed within a QFN package modified for that purpose.

An embodiment of a package in accordance with the present invention comprises a lead frame comprising a diepad and a conducting element extending out of the package and not integral with the diepad. A die is supported on a first side by the diepad, and a conducting ribbon provides electrical contact between the conducting element and a second side of the die opposite the first side.

An embodiment of a method in accordance with the present invention for packaging a vertical conduction die, comprises, providing a conducting ribbon in electrical contact with a first side of the die opposite a second surface of the die in electrical contact with a diepad, and a conducting element extending out of the package and not integral with the diepad.

An embodiment of a conducting ribbing in accordance with the present invention has a first portion configured to be in electrical communication with a contact on a surface of a die supported on a second surface by a diepad, and a second portion configured to be in electrical communication with a conducting element extending out of a package housing the die and the ribbon, the conducting element not integral with the diepad.

These and other embodiments of the present invention, as well as its features and some potential advantages are described in more detail in conjunction with the text below and attached figures.

### BRIEF DESCRIPTION OF THE DRAWINGS

FIG. 1A shows a simplified cross-sectional view of the area offered by a set of bond wires and an Aluminum ribbon.

FIG. 1B shows the vertical profile offered by an aluminum bond wire and an Aluminum ribbon.

FIG. 2A shows a simplified a plan view of an embodiment of a package in accordance with the present invention housing a single vertical conduction die and having contact with a top surface thereof established with an aluminum bonding ribbon.

FIG. 2B shows a simplified cross-sectional view of the package of FIG. 2A.

FIG. 3 shows a simplified plan view of an alternative embodiment of a package in accordance with the present invention housing two dies.

FIGS. 4A-B show simplified perspective and plan views, respectively, of the layout of a conventional QFN package.

FIGS. 5A-5F show simplified plan views of various resistance versus die size options of a QFN package modified in accordance with embodiments of the present invention.

FIGS. 6A-6C show comparative die sizes for various options of bonding arrangements of the die on the diepad of different package types.

FIGS. 7A-D demonstrate extension of the layout rules according to certain embodiments in accordance with the present invention, to 4×4 mm and 3×3 mm packages housing single or dual Mosfet die.

FIG. 8A shows a simplified plan view of another conventional package configuration that is closely related to the QFN.

FIG. 8B illustrates a simplified plan view of the layout of the DFN package of FIG. 8A, which utilizes Aluminum ribbon connections to the Source.

FIG. 8C shows the “standard” 3×3 mm QFN package (9 mm² footprint) substituted for the 2×5 mm QFN package (10 mm²).

FIGS. 9A through FIG. 9C demonstrate packages housing commonly used combinations of Mosfets with PICs, other Mosfets and other active devices like Schottky diodes.

### DETAILED DESCRIPTION OF THE INVENTION

Device packages in accordance with certain embodiments of the present invention involve the use of Aluminum ribbons, rather than bond wires, to establish low resistance contacts with at least one surface of a vertical conduction die.

Orthodyne Electronics of Irvine, Calif., a leading manufacturer of Aluminum wire bonders, has recently released a series of machines that are capable of bonding Aluminum ribbons that vary in width and thickness from 20 mils wide×2 mils thick, up to 80 mils wide×10 mils thick. TABLE A lists the bond wire diameter cross section versus dimensions of electrically comparable Aluminum ribbons.

TABLE A

| | | Wire Diameter | | | | | | | |
|---|---|---|---|---|---|---|---|---|---|
| | | 5 mil | 8 mil | 10 mil | 12 mil | 14 mil | 15 mil | 16 mil | 20 mil |
| RIBBON | 20 × 2 mil | 2.0 | 0.8 | 0.5 | 0.4 | 0.3 | 0.2 | 0.2 | 0.1 |
| | 20 × 3 mil | 3.1 | 1.2 | 0.8 | 0.5 | 0.4 | 0.3 | 0.3 | 0.2 |
| | 30 × 3 mil | 4.6 | 1.8 | 1.1 | 0.8 | 0.6 | 0.5 | 0.4 | 0.3 |
| | 40 × 4 mil | 8.1 | 3.2 | 2.0 | 1.4 | 1.0 | 0.9 | 0.8 | 0.5 |
| | 40 × 6 mil | 12.2 | 4.8 | 3.1 | 2.1 | 1.6 | 1.4 | 1.2 | 0.8 |
| | 60 × 6 mil | 18.3 | 7.2 | 4.6 | 3.2 | 2.3 | 2.0 | 1.8 | 1.1 |
| | 60 × 8 mil | 24.4 | 9.5 | 6.1 | 4.2 | 3.1 | 2.7 | 2.4 | 1.5 |
| | 80 × 6 mil | 24.4 | 9.5 | 6.1 | 4.2 | 3.1 | 2.7 | 2.4 | 1.5 |
| | 80 × 8 mil | 32.6 | 12.7 | 8.1 | 5.7 | 4.2 | 3.6 | 3.2 | 2.0 |
| | 80 × 10 mil | 40.7 | 15.9 | 10.2 | 7.1 | 5.2 | 4.5 | 4.0 | 2.5 |

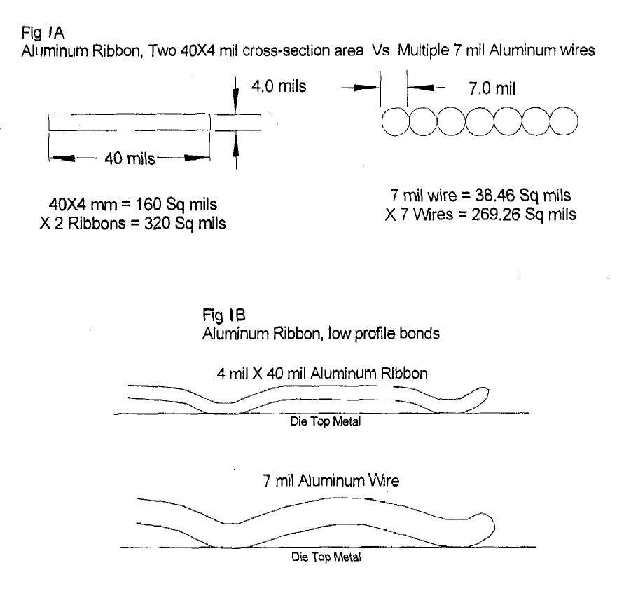

FIG. 1A compares cross-sectional views of two different approaches for establishing contacts of approximately the same electrical resistance, with a die surface. In the conventional approach, seven aluminum bond wires, each having a diameter of 8 mils, offer a combined cross-section of 351 mils². By contrast, two 40 mil×4 mil Aluminum ribbons in accordance with an embodiment of the present invention, offer a combined cross-section of 320 mils². The greater cross-section offered by the Aluminum ribbons as compared with the bond wires, desirably reduces the electrical resistance offered by the connection.

Moreover, FIG. 1B compares the vertical profile offered by the two approaches shown in FIG. 1A. FIG. 1B shows that being thinner, the Aluminum ribbon exhibits a lower loop-height. Such a lower loop-height can allow for an increase in the thickness of the plastic over the die. Alternatively, the lower loop height can allow for the thickness of the package to be decreased, without compromising the amount of plastic covering the die. This results in a highly desirable reduction in vertical profile of the package.

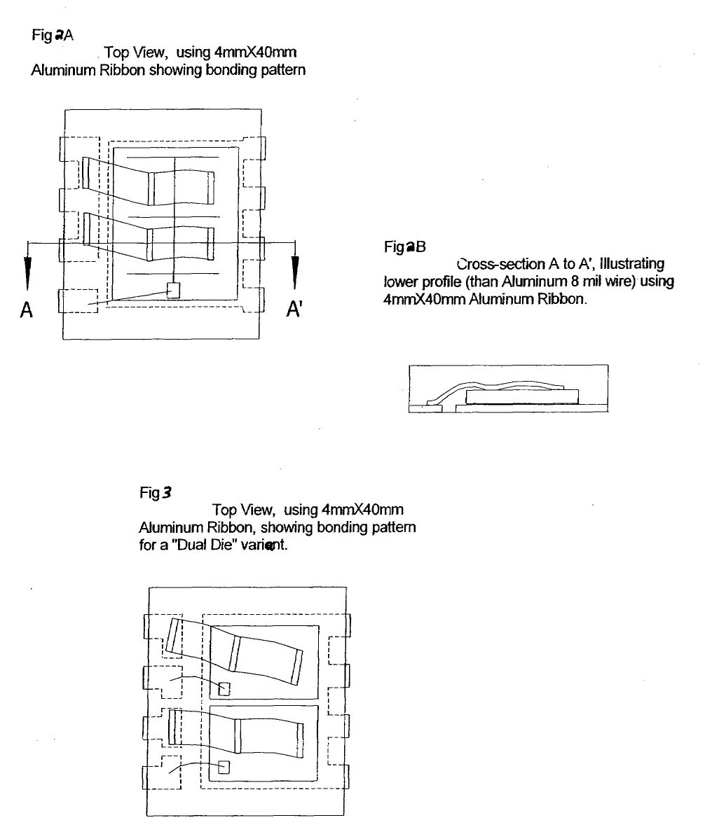

FIG. 2A shows a simplified plan view of an embodiment of a package in accordance with the present invention utilizing an Aluminum ribbon bonding pattern. FIG. 2B shows a simplified cross-sectional view of the package of FIG. 2A taken along line A-A′ of FIG. 2A. The pair of 4 mm×40 mm Aluminum ribbons used to establish electrical contact with the die surface, allows the embodiment of the package shown in FIGS. 2A-B to exhibit a reduced vertical profile as compared with the equivalent package utilizing conventional bond wires.

The embodiment of FIG. 2A does show a bond wire connecting the gate contact with an adjacent pin. Contact with the gate, however, does not require a high voltage. Accordingly, the diameter (e.g. 4 mils or 0.1 mm) of the gate contact bond wire is smaller than the diameter (e.g. 8 mils) of the bond wires conventionally employed to establish the source contact. Thus even if the bonding profile of the bond wire and ribbon are assumed to be the same, the reduction in height attributable to use of only the remaining gate bond wire having a smaller diameter (4 mils vs. 8 mils), would represent more than 10% of the total thickness of the package.

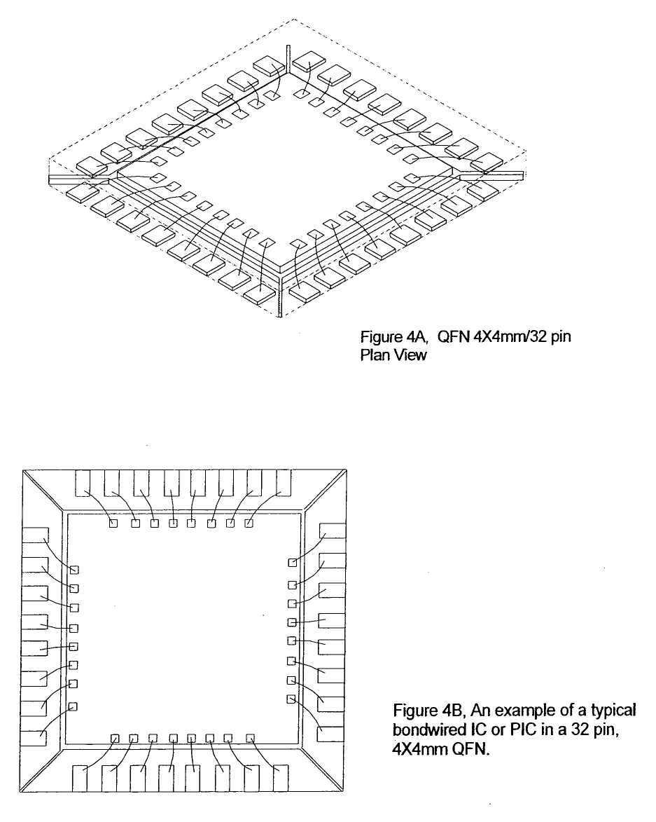

While the specific embodiment of the package shown in FIGS. 2A-B houses a single die, embodiments in accordance with the present invention are not limited to this configuration. In alternative embodiments, a package could house more than one die and still remain within the scope of the present invention. Thus, FIG. 3 shows a simplified plan view of an another embodiment of a package layout in accordance with the present invention, which utilizes separate Aluminum ribbons to bond to the top surfaces of a pair of die housed within the package.

The embodiment shown in FIG. 3 highlights one aspect of the use of Aluminum ribbon bonding. Specifically, many existing power management packages were designed for wire bonding, which requires the wire to be bonded at relatively acute angles and pulled in tight radius turns. However, owing to the thin/wide shape of the Aluminum ribbons, it is not as easy to bend them laterally in order to align them with the die or leadframe bond header, to make it conform to existing packages. Thus in the embodiment shown in FIG. 3, the Aluminum ribbon is depicted as making a slightly angled connection with the top surface of the die. Taking into account this angled connection, and the width of the boding header on the dual die leadframe, the width of the ribbon is restricted, contributing to series resistance.

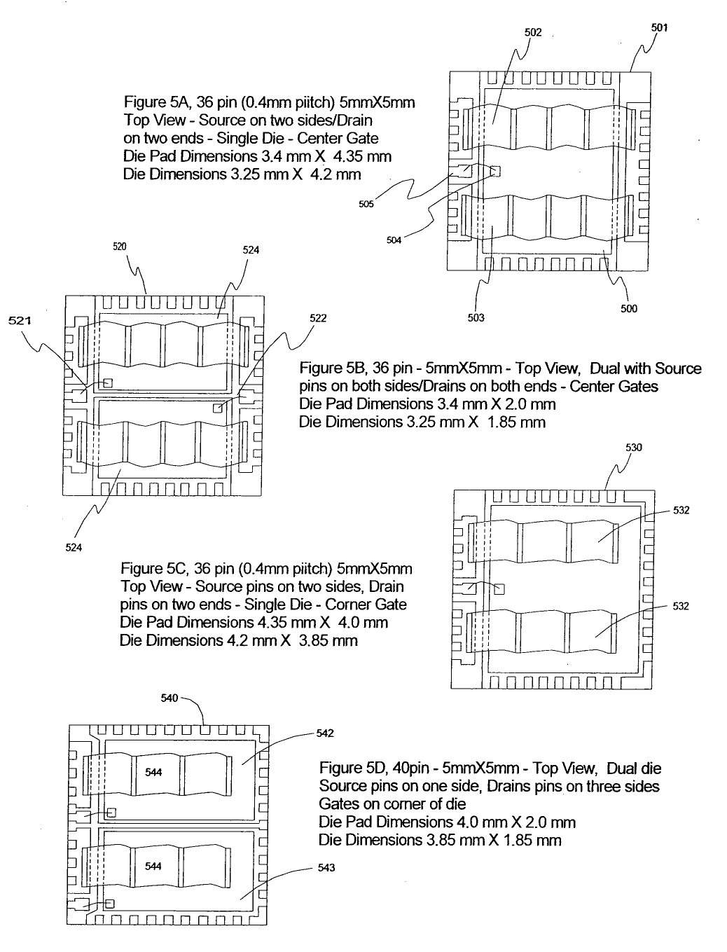

In accordance with embodiments of the present invention, the inventors have discovered that modification of a conventional package type may facilitate the use of aluminum bonding patterns to establish low electrical resistance contacts with die surfaces. Specifically, the “Quad Flat No-lead” (QFN) is a family of JEDEC registered packages featuring internal die placement, bonding, and construction that optimize connection to the power die to maximize the ratio of die size to package footprint ratio, minimize the package electrical and thermal resistance, and meet JEDEC registered external package dimensions. FIGS. 4A-B show simplified perspective and plan views, respectively, of a conventional QFN package utilizing bond wires to establish electrical contact with the top surface of the die housed therein.

Particular embodiments in accordance with the present invention adapt the QFN and other package designs to accommodate vertical conduction, power management devices. This approach offers several alternatives to improve upon the way the class of power management semiconductor devices have previously conventionally been packaged.

For example, one difference between conventional packaging for power management devices and the QFN package as shown above, is that QFNs generally have much finer lead pitch, smaller leads, and many more leads, and the leads are located on all four sides of the package. With packages for integrated circuits (ICs), the pin-count has increased over time to accommodate die having more and more electrical connections. By contrast, with discrete products like Mosfets and with small power management integrated circuits (PICs), the number of electrical connections is usually modest, and the high pin counts of certain existing packages are usually present to make up for poor thermal resistance, by adding many leads in parallel.

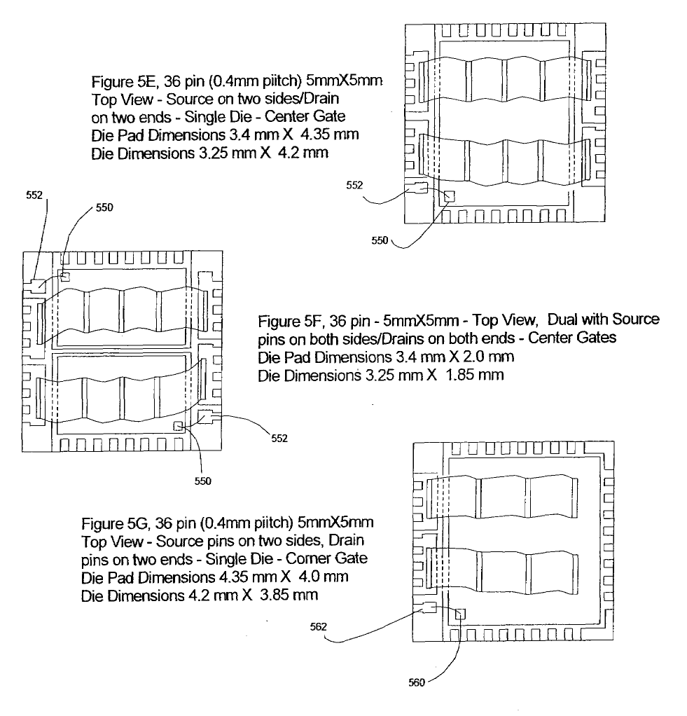

However, with the 16 to 50 pin modified QFN packages disclosed by embodiments in accordance with the present invention, the high pin count offers flexibility to orient the die and “ganged”/integral pins, allowing accommodation of Aluminum ribbon bonding patterns with minimal direction changes, to create low thermal and electrical resistance contacts with the die. For example, in accordance with particular embodiments of the present invention, ends of an Aluminum ribbon may bond with pins on opposite sides of the package, with the center of the ribbon making contact with the die surface. TABLE B below summarizes certain characteristics of the QFN packages of FIGS. 5A-F that have been modified in accordance with embodiments of the present invention.

TABLE B

| | PACKAGE | | PIN | DIE PAD | | DIE | DIE |
|---|---|---|---|---|---|---|---|
| FIG | DIMENSIONS | PIN | PITCH | DIMENSIONS | # OF | DIMENSIONS | AREA |
| NO. | (mm) | COUNT | (mm) | (mm) | DIE | (mm) | (mm²) |
| 5A | 5 × 5 | 36 | 0.4 | 3.4 × 4.35 | 1 | 3.25 × 4.2 | 13.65 |
| 5B | 5 × 5 | 36 | 0.4 | 3.4 × 2.0 | 2 | 3.25 × 1.85 | 6.012 |
| 5C | 5 × 5 | 36 | 0.4 | 4.0 × 4.35 | 1 | 3.85 × 4.2 | 15.96 |
| 5D | 5 × 5 | 40 | 0.4 | 4.0 × 2.0 | 2 | 3.85 × 1.85 | 7.123 |
| 5E | 5 × 5 | 36 | 0.4 | 3.4 × 4.35 | 1 | 3.25 × 4.2 | 13.65 |
| 5F | 5 × 5 | 36 | 0.4 | 3.4 × 2.0 | 2 | 3.25 × 1.85 | 6.012 |
| 5G | 5 × 5 | 36 | 0.4 | 4.0 × 4.35 | 1 | 3.85 × 4.2 | 15.96 |

Achieving the lowest total electrical resistance for any size QFN package and any configuration in that package, likely involves tradeoffs and may not result in one preferred configuration for all combinations. For example, FIG. 5A shows a simplified plan view of a the layout for a single Mosfet die positioned in a 36 pin 5×5 mm QFN package 501 modified in accordance with an embodiment of the present invention. In this particular embodiment, the single Mosfet die 500 has a bondwired lead connection 505 to Gate contact 504 in the center of one side of the die. This orientation allows a symmetrical ribbon bonding arrangement and easily accommodates two 4×40 mil ribbons 502 and 503.

FIG. 5B shows a simplified plan view of the layout of an alternative embodiment of a package 520 in accordance with the present invention. The embodiment of FIG. 5B utilizes the same kind of center (lead) gate connections 521 and 522 as in the embodiment of FIG. 5A, with the package 520 enclosing two Mosfet die 524 instead of one.

In the layouts of both FIGS. 5A-B, the resistance contribution of the Aluminum ribbons have been minimized by connecting across the top surface of the die, to the leadframe on both sides. Such a bonding approach may be compared with that of FIG. 5C, which shows a simplified plan view of the layout of an alternative embodiment of a package 530 in accordance with the present invention. Specifically, the Aluminum ribbons 532 of the package 530 of FIG. 5C connects the Source to the leadframe on only one side of the housed die.

Connecting the Source on both sides of the package in the manner of the embodiments of FIGS. 5A and 5B, cuts the series bond ribbon resistance in half, from approximately 0.4 mOhm to approximately 0.20 mOhm. However, this reduced resistance is achieved at the expense of an approximately 20% decrease in die size. The impact of the decreased die size is then a function of the resistance of the die. In this example, a die the size shown in FIGS. 5A-B, in a state-of-the-art low voltage Mosfet technology, will exhibit a total die resistance of approximately 1 mOhm. In this case, the 20% decrease in die size will add approximately 0.2 mOhm. This can be compared with bonding the Source off of both sides of the package, to reduce the bonding ribbon by half, which also reduces the total resistance by about 0.2 mOhms. Thus here, the decision whether or not to bond the ribbon on both sides of the leadframe, would probably be made based upon economic terms (Silicon area vs. ribbon bonds), or based upon measures of performance like switching speed, rather than just the resistance alone.

As Mosfet breakdown voltage ratings increase, the resistance of a Mosfet of this size will also increase—and a 20% penalty in die size will result in a larger penalty in die resistance, so the maximum die size will probably be the choice if the highest absolute lowest resistance is the goal.

The bonding diagrams of FIGS. 5A, B, and C would work well using a 36 pin 5×5 mm QFN package. However, the gate arrangement on an embodiment of dual die package may be improved using a modified QFN package of the same size, but having 40 pins instead of 36. Specifically, FIG. 5D shows a simplified layout of such a QFN package 540 modified to house dual die 543 with ribbon bonding 544 of the Source contact to only one side of the leadframe.

Since the dual die of FIGS. 5B and 5D occupy an area slightly less than one-half the area of the single die housed by the embodiments of FIGS. 5A and 5C, the resulting resistance is slightly more than double that of the single die. And, since each die has only a single ribbon of the same size as the two ribbons used on the dual die embodiments—the Aluminum bonding ribbon and the Mosfet both still contribute about the same percentage of the total series electrical resistance.

The embodiments of FIGS. 5C-D illustrate Aluminum ribbons bonded to Source pins on only one side of the package. The pins on the remaining three sides of the package are all integral with the diepad, maximizing the diepad area available to be occupied by the die. This arrangement allows an increased area of the diepad usable by the die, at the expense of a fraction of a mOhm of added package resistance.

Still an additional consideration in designing packages is that the percentage difference in die size changes for different packages sizes. For example, the minimum spacing required to isolate the die on both sides is a fixed value. However, this value is a smaller percentage of the overall package size, as the size of the package increases.

A pinout that brings the Gate connection out between Source pins, for example as shown in the embodiments of FIGS. 5A-B, permits the most symmetrical layout of the die and package layout and allows the most direct access for ribbon bonding. From the standpoint of P.C. board layout, since the Source pins are often connected directly to an inner power or ground plane through “vias”, getting traces to the Gate connection between the Source connections, does not usually pose a problem.

In the rare cases where the Source and Gate must be connected on a single P.C. board layer, FIGS. 5E through 5F provide simplified plan views of the layouts of 5×5 mm QFN packages having 36 pins, with the same two single and two dual ribbon bonding/pin-out options as FIGS. 5A-B. In the embodiments of FIGS. 5E-F, however, the Gate bond pad 550 and pin 552 are relocated to one corner (in the single die package of FIG. 5E) or to opposing corners (in the dual die package of FIG. 5F). The same die sizes and the same bonding ribbon resistance result. So the same die/package resistance ratios still apply. However, the slightly awkward bonding angles on smaller packages may restrict the width of the ribbon that can be accommodated.

The corner Gate option shown in the embodiment of FIG. 5G, can be applied with the single die embodiment of FIG. 5C. As with the previous discussion, using 40×4 mil ribbons the bonding paths across the Source top metal can still be optimized. However, if the ribbon width is increased or the die size is decreased in smaller packages, the corner Gate packaging option may limit available bonding configurations.

The above discussion reveals that the plurality of leads of the high pin count modified QFN packages in accordance with embodiments of the present invention, imparts greater flexibility to the design of the package. Specifically, the large number of available pins allows the designer to choose the optimal internal connections for a given die from a large number of possibilities, while still meeting the relevant JEDEC standard for package footprint. The minimum pitch and lead width of the QFN package also offer alternatives to bond the Gate and other less resistance critical electrical connections to the outside world, without wasting a lot of area on the leadframe.

The ribbon pattern in the embodiments of FIGS. 5E and 5G are acceptable when 40 mil wide ribbons are used in a 5×5 mm package. But, using corner pins for Gate connections is slightly less optimal for 40 mil ribbon in smaller packages, or if the width of the ribbon is to be maximized in the 5×5 mm package. Bonding the ribbon in anything less than a straight line, compromises some area and causes stress and tension on the bonds during the bonding process. Such stresses may, or may not be sufficient to cause reliability concerns with the structures under the Source metal, or with the integrity of the ribbon/Source metal bond.

Another advantage of using the QFN style package, adapted in accordance with the present invention, is that the area between the individual pins serves to seal to the plastic around the edge of the package. Specifically, certain conventional package designs feature a continuous tab portion that obstructs continuity between the top and bottom plastic portions of the package body. This results in the package having to be thicker to maintain it's integrity, as the top plastic and bottom plastic are not connected for a major portion of a side area. Such conventional package designs may be contrasted with the high pin-count QFN style package, which divides the side into many pins and the top and bottom plastic are connected and continuous between the pins.

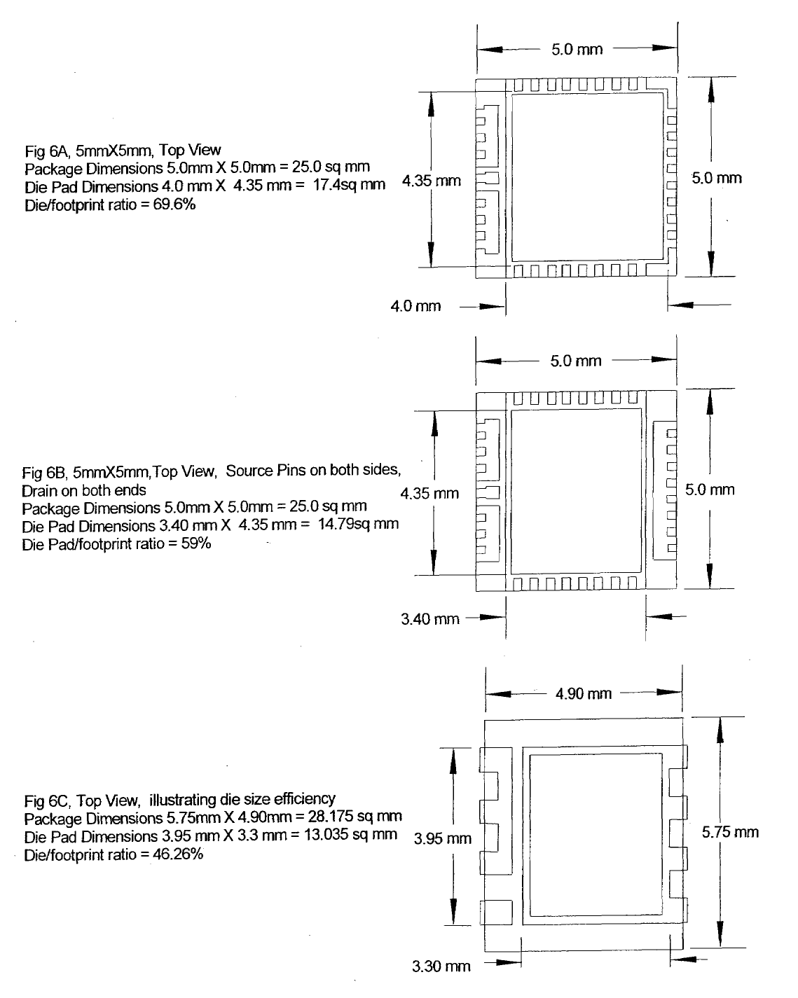

FIG. 6A presents a simplified plan view of an embodiment of a QFN package design as modified according to the present invention to house a vertically conducting power switching device. FIG. 6B presents a simplified plan view of an alternative embodiment of a QFN package design modified in accordance to the present invention to house a vertically conducting power switching device.

The layouts of the embodiments of the modified QFN packages of FIGS. 6A-B may be compared with that of FIG. 6C, which corresponds with the non-QFN package design shown in FIGS. 2A-B and 3. TABLE C summarizes the relative dimensions of these three package designs.

TABLE C

| Package | | | Die/footprint ratio |
|---|---|---|---|
| Figure | PC Board Area | Die Pad (S) | (efficiency) |
| 6A | 5 mm × 5 mm = 25 mm² | 4.0 mm × 4.35 mm = 17.4 mm² | 69.6% |
| 6B | 5 mm × 5 mm = 25 mm² | 3.4 mm × 4.35 mm = 14.79 mm² | 59% |
| 6C | 5.75 mm × 4.9 mm = 28.2 mm² | 3.95 mm × 3.3 mm = 13.035 mm² | 46.26% |

TABLE C indicates that both examples of the modified QFN package design of the present invention, results in a larger die in a smaller footprint, as compared with other than a modified QFN package approach (FIG. 6C), even one featuring Aluminum ribbon bonding. And, FIG. 6A demonstrates a similar pinout arrangement as the package of FIG. 5C, thereby allowing the Source to be bonded off of one side of the die, and the Drain to be contacted along the opposite side of the package (as well as both ends and underside of the QFN style package for maximum thermal transfer). This results in a 16% improvement in space utilization. So, this is a standard JEDEC outline package, with a smaller footprint, a larger die, in a thinner (0.8 mm max) surface mount package with improved thermal and electrical performance.

In general, over the range of Mosfet die sizes and technologies suited to the package styles according to embodiments of the present invention, the ribbon bonds can be configured to keep the package resistance between about 15-30% of the total resistance represented by the sum of the package and die resistance. In particular embodiments, the conducting ribbons employed by the present invention are configured to exhibit a resistance of less than about 0.5 mOhm for packages enclosing a single Mosfet die. For packages enclosing dual Mosfet die, the conducting ribbon would be expected to exhibit a resistance of about 1.0 mOhm or less.

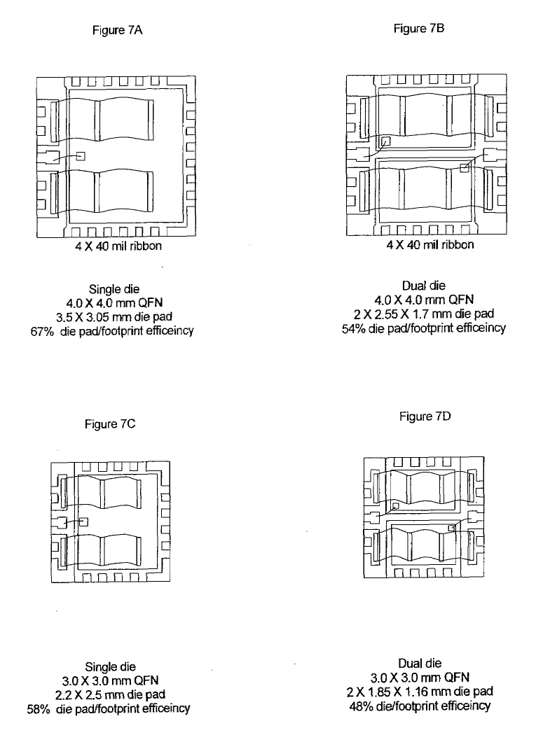

FIGS. 7A-D demonstrate extension of the layout rules according to certain embodiments in accordance with the present invention, to 4×4 mm and 3×3 mm packages housing single or dual Mosfet die. The same rule still applies: the largest die and most optimized bonding angles are achieved with the maximum number of pins. In the case of the 4×4 mm packages of FIGS. 7A and 7B, the largest die and most optimized bonding angles are achieved with a pin count of 28 and a pin pitch of 0.4 mm. In the case of the 3×3 mm packages of FIGS. 7C and 7D, the largest die and most optimized bonding angles are achieved with a pin count of 20 and a pin pitch of 0.4 mm. TABLE D summarizes certain characteristics of the die shown in FIGS. 7A-D.

TABLE D

| | | | | Die Pad/ |
|---|---|---|---|---|
| FIG. | No. of Die | QFN Footprint | Die Pad Footprint | Footprint |
| No. | Housed | (mm) | (mm) | Efficiency (%) |
| 7A | 1 | 4 × 4 | 3.5 × 3.05 | 67 |
| 7B | 2 | 4 × 4 | 2.55 × 1.7 | 54 |
| 7C | 1 | 3 × 3 | 2.2 × 2.5 | 58 |
| 7D | 2 | 3 × 3 | 1.85 × 1.16 | 48 |

The above description has discussed modification of a QFN-type package (conforming to JEDEC specification MO-220), in order to accommodate vertical conduction devices. However, the present invention is not limited to this particular embodiment, and alternatives embodiments utilize other package types. For example, JEDEC specification no. MO-243 describes a newer variation of the QFN package, and alternative embodiments in accordance with the present invention could conform to this specification. Other specifications cover QFN type packages, and various embodiments in accordance with the present invention could conform to those package specifications.

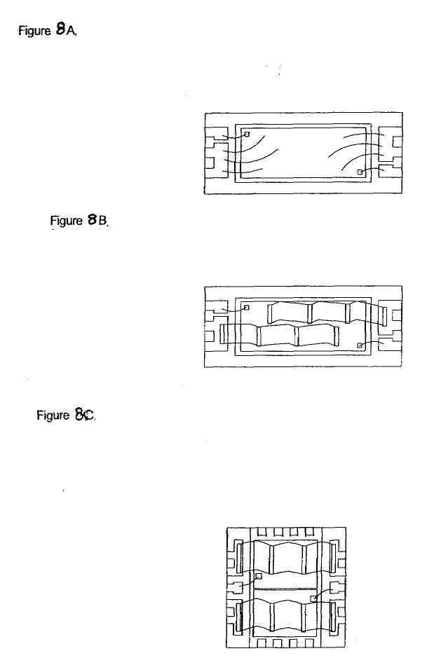

In addition, FIG. 8A shows a simplified plan view of another conventional package configuration that is closely related to the QFN. Specifically, the 2×5 mm “DFN style” (JEDEC specification MO-229) package shown in FIG. 8A has pins along only two sides. Although DFN style packages are in wide use, the 2×5 mm size package is employed almost exclusively for a “Reverse Blocking Mosfet Switch”. A Reverse Blocking Mosfet switch comprises two vertical conduction Mosfets having a common Drain as the base of the Mosfet. In this configuration, when both Mosfets are turned off, the intrinsic diode in each Mosfet blocks the forward biased conduction of the intrinsic diode of the other Mosfet. This configuration is used in many products that have multiple power sources. The same Mosfet configuration is also common in smart and protected batteries. Using the die pad size and arrangement shown, the conventional DFN package illustrated in FIG. 8A demonstrates an available die pad area of 3.05 mm×1.5 mm=4.57 mm² (46% efficiency).

FIG. 8B illustrates a simplified plan view of the layout of the DFN package of FIG. 8A, which utilizes Aluminum ribbon connections to the Source. FIG. 8B illustrates that attempting to lower the impedance and cost by simply switching to Aluminum ribbon bonding in the DFN package of FIG. 8A, may not yield a significant gain. Specifically, in this embodiment the maximum ribbon width is 20 mils, owing to the locations of the contacts on the narrow ends of the package, and the narrow aspect ratio of the die. As the ribbon has a thickness of only 2 mils, the embodiment of FIG. 8B offers only ¼ the cross-section area of the 4×40 mil ribbons used in the previous examples.

In FIG. 8C, the “standard” 3×3 mm QFN package (9 mm² footprint) is substituted for the 2×5 mm DFN package (10 mm²). In this case, the die pad area increases about 9%, as the package footprint is reduced by 10% (1 mm²). The die accommodated with the reverse blocking configuration occupy an area of 2.57×2.02 mm=5.2 mm², a gain in die pad size of approximately 9% over the configuration of FIG. 8B. In addition, the package now accommodates two, 40×4 mil Aluminum ribbons with approximately half the distance between the die contacts and leadframe Source contacts, as with the package of the previous example (FIG. 8B).

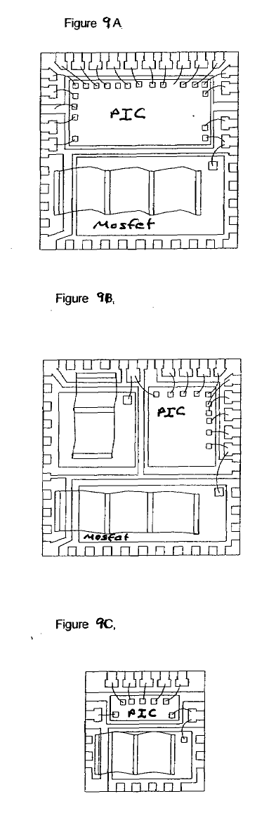

FIGS. 9A through FIG. 9C demonstrate packages housing commonly used combinations of Mosfets with PICs, other Mosfets and other active devices like Schottky diodes, as summarized in TABLE E.

TABLE E

| FIG. No. | QFN Dimensions (mm) | Die Housed |
|---|---|---|
| 9A | 5 × 5 | Mosfet and PIC |
| 9B | 5 × 5 | 2 Mosfets and PIC, or Mosfet, |
| | | Schottky and PIC |
| 9C | 3 × 3 | Mosfet and PIC |

Here, an objective is to be able to house the desired devices in such a manner that they can be interconnected. In the case of any high current connections to the Mosfets or Schottky diodes, another objective is to provide a layout that will allow the devices to be bonded with Aluminum ribbon that has a clear path to connect directly to a leadframe header with enough room to accommodate the ribbon bond. Non-power connections can be accomplished using a thinner Aluminum bondwire. It is possible that even smaller diameter Gold or Copper wire could be used for non-power interconnects, on the same die that uses Aluminum ribbon for the power connections. In such embodiments, the top metal and spot-plating in contact areas of the leadframe, should be made compatible.

While the above is a full description of the specific embodiments, various modifications, alternative constructions and equivalents may be used. Therefore, the above description and illustrations should not be taken as limiting the scope of the present invention which is defined by the appended claims.

What is claimed is:

1. A package comprising:
a lead frame comprising,
a diepad, and
a conducting element extending out of the package and not integral with the diepad,
a die supported on a first side by the diepad; and
a conducting ribbon providing electrical contact between the conducting element and a second side of the die opposite the first side.

2. The package of claim 1 wherein the conducting ribbon also provides electrical contact between the second side of the die and a second conducting element extending out of the package on a side opposite the first conducting element, the second conducting element not integral with the diepad.

3. The package of claim 1 wherein the die comprises a vertical conduction die.

4. The package of claim 3 wherein the vertical conduction die comprises a Mosfet.

5. The package of claim 4 wherein the conducting ribbon provides an electrical contact with a source contact of the Mosfet.

6. The package of claim 4 wherein the leadframe further comprises a second conducting element extending out of the package and integral with the diepad, the second conducting element providing electrical contact with a drain of the Mosfet.

7. The package of claim 4 wherein the leadframe further comprises a second conducting element extending out of the package and not integral with the diepad, the package further comprising a bond wire providing electrical contact between the second conducting element and a gate contact of the Mosfet.

8. The package of claim 1 wherein the conducting ribbon comprises Aluminum.

9. The package of claim 1 wherein dimensions of the package conform to JEDEC specification MO-229, MO-220, or MO-243.

10. The package of claim 1 further comprising:
a second die supported on the diepad; and
a second conducting ribbon providing electrical contact between the second die and a second conducting element extending outside the package and not integral with the diepad.

11. The package of claim 10 wherein the die and the second die comprise Mosfets connected in a reverse blocking configuration.

12. The package of claim 10 wherein the second die comprises a Mosfet, a power integrated circuit (PIC), or Schottky diode.

13. A method of packaging a vertical conduction die, the method comprising providing a conducting ribbon in electrical contact with,
a first side of the die opposite a second surface of the die in electrical contact with a diepad, and
a conducting element extending out of the package and not integral with the diepad.

14. The method of claim 13 wherein the conducting ribbon also provides electrical contact between the first side of the die and a second conducting element extending out of the package on a side opposite the first conducting element, the second conducting element not integral with the diepad.

15. The method of claim 13 wherein the die comprises a Mosfet, and the conducting ribbon is in electrical contact with a source contact.

16. A conducting ribbing having,
a first portion configured to be in electrical communication with a contact on a surface of a die supported on a second surface by a diepad, and
a second portion configured to be in electrical communication with a conducting element extending out of a package housing the die and the ribbon, the conducting element not integral with the diepad.

17. The conducting ribbon of claim 16 further comprising a third portion configured to be in electrical communication with a second conducting element extending out of the package on a side opposite the first conducting element, the second conducting element not integral with the diepad.

18. The conducting ribbon of claim 16 comprising Aluminum.

19. The conducting ribbon of claim 16 having a cross-sectional area of between about 40-800 mil².

20. The conducting ribbon of claim 16 configured to exhibit a resistance of about 1 mOhm or less in electrical communication with a source contact of a Mosfet die.
